(19) United States
(12) Patent Application Publication
(10) Pub. No.: US 2017/0288676 A1
(43) Pub. Date: Oct. 5, 2017

(54) COMMUNICATION APPARATUS, SEMICONDUCTOR DEVICE, AND FREQUENCY CHARACTERISTIC CHANGING METHOD

(71) Applicant: FUJITSU LIMITED, Kawasaki-shi (JP)

(72) Inventors: Ryuta Hoshi, Meguro (JP); Masato KOBAYASHI, Oyama (JP); Yasuhiro OBA, Yokohama (JP); YUKI MURAKAMI, Kawasaki (JP); Takao YASUI, Iwakura (JP); Masao MAEDA, Nishinomiya (JP); Masato Hashizume, Souraku (JP); Yusuke Tanaka, Osaka (JP); Tatsuru MISAKI, Kawasaki (JP); YUUTAROU TATEISHI, Kawasaki (JP)

(73) Assignee: FUJITSU LIMITED, Kawasaki-shi (JP)

(21) Appl. No.: 15/445,153

(22) Filed: Feb. 28, 2017

(30) Foreign Application Priority Data
Mar. 31, 2016 (JP) 2016-072938

(51) Int. Cl. H03K 19/177; H03K 19/173

(52) U.S. Cl. CPC H03K 19/17764; H03K 19/1776; H03K 19/17784; H03K 19/1736; H03K 19/17792

(57) ABSTRACT

The communication apparatus includes a logical device, a wiring line, and a changing unit; the logical device is a programmable device; the wiring line supplies a voltage to the logical device; and the changing unit changes a frequency characteristic of the wiring line based on an operating characteristic obtained by monitoring of the operating characteristic of the logical device for operating by receiving supply of the voltage. According to this, occurrence of voltage drop can be suppressed even if a circuit configured in a programmable logical device is changed.

### CROSS-REFERENCE TO RELATED APPLICATION

This application is based upon and claims the benefit of priority of the prior Japanese Application No. 2016-72938 filed on Mar. 31, 2016 in Japan, the entire contents of which are hereby incorporated by reference.

### FIELD

The present invention relates to a communication apparatus, a semiconductor device, and a frequency characteristic changing method.

### BACKGROUND

There are cases where a programmable logical device is used for a communication apparatus. As the logical device, an FPGA (Field Programmable Gate Array) chip (hereinafter, simply referred to as an FPGA) is known. The semiconductor device causes a storage area of a memory disposed along with the FPGA to store the configuration data obtained by describing a circuit in high-level languages and the like during operation and compiling the description. During operation of the FPGA, the configuration data are read from the memory, the described circuit is implemented in the FPGA, and the circuit operates.

With the FPGA, the circuit in the FPGA can be changed without replacing of hardware components even after the manufacture of the communication apparatus is completed.

Patent Document 1 WO 2015/033422

Patent Document 2 JP 2004-325383 A

Due to miniaturization and high integration of semiconductor processes in recent years, the supply voltage to be supplied to the FPGA tends to decrease and the current tends to increase. In addition, a large board has come to be used as a mounting board on which the FPGA is to be mounted due to the increased number of pins of a board accompanied by a high degree of integration, and the influence of the characteristic of the power supply pattern on the board (power supply wiring line) on the power supply circuit has become unignorable.

For example, when the anti-resonance frequency of the power supply pattern and the peak frequency of the consumption current, for example, when the load of the FPGA suddenly changes becomes equal, a sharp voltage drop of the power supply circuit (hereinafter, sometimes referred to as a voltage drop) may occur due to the anti-resonance. When the voltage drop occurs during operation of the circuit configured inside the FPGA and a malfunction of the FPGA occurs, it is difficult to specify the cause of the malfunction.

In addition, in order for the communication apparatus to achieve high-speed transmission, it is preferable that the FPGA device to be used for the communication apparatus operates stably over a wide range of frequencies.

### SUMMARY

In one aspect, the communication apparatus includes a logical device, a wiring line, and a changing unit. The logical device includes a programmable device. The wiring line supplies a voltage to the logical device. The changing unit changes a frequency characteristic of the wiring line based on an operating characteristic obtained by monitoring of the operating characteristic of the logical device configured to operate by receiving supply of the voltage.

In one aspect, the semiconductor device includes the logical device, the wiring line, and the changing unit. The logical device includes the programmable device. The wiring line supplies a voltage to the logical device. The changing unit changes the frequency characteristic of the wiring line based on the operating characteristic obtained by monitoring of the operating characteristic of the logical device configured to operate by receiving supply of the voltage.

In one aspect, the frequency characteristic changing method includes changing the frequency characteristic possessed by the wiring line configured to supply a voltage to a programmable logical device, based on the operating characteristic obtained by monitoring of the operating characteristic of the logical device configured to operate by receiving supply of the voltage.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1A is a schematic top view of an FPGA device, and FIG. 1B is a schematic side view of the FPGA device;

FIG. 2 is a flowchart illustrating an operation of the FPGA device;

FIG. 3 is an equivalent circuit diagram of the FPGA device;

FIG. 4 is a diagram illustrating an example of an impedance characteristic with respect to frequency fluctuation of a consumption current of the FPGA device;

FIG. 5 is a diagram illustrating an example of an impedance characteristic with respect to frequency fluctuation of the consumption current of the FPGA device and a consumption current characteristic of the FPGA device;

FIG. 6 is a diagram illustrating an example of a change of a voltage characteristic with respect to an operating time of the FPGA device;

FIG. 7 is an equivalent circuit diagram of the FPGA device according to a first embodiment;

FIG. 8 is a schematic side view of the FPGA device according to the first embodiment;

FIG. 9 is a flowchart illustrating an example of processing for changing an anti-resonance frequency of the FPGA device according to the first embodiment;

FIG. 10 is a schematic top view of the FPGA device according to the first embodiment;

FIG. 11 is a flowchart illustrating another example of processing for changing an anti-resonance frequency of the FPGA device according to the first embodiment;

FIG. 12 is a schematic top view of the FPGA device according to a second embodiment;

FIG. 13 is a flowchart illustrating an example of processing for changing an anti-resonance frequency of the FPGA device according to the second embodiment;

FIG. 14 is a schematic top view of the FPGA device according to a third embodiment;

FIG. 15 is a functional block diagram of an optical transmission apparatus including an FPGA device according to an embodiment; and

FIG. 16 is a flowchart illustrating an example of configuration data change processing of the FPGA device according to an embodiment.

### DESCRIPTION OF THE PREFERRED EMBODIMENTS

In the following, embodiments will be described with reference to the accompanying drawings. However, the embodiments described below are merely illustrative and are not intended to exclude various modifications and applications of techniques not specified below. It should be noted that in the drawings used in the following embodiments, the portions denoted by the identical reference numerals represent identical or similar portions unless otherwise specified.

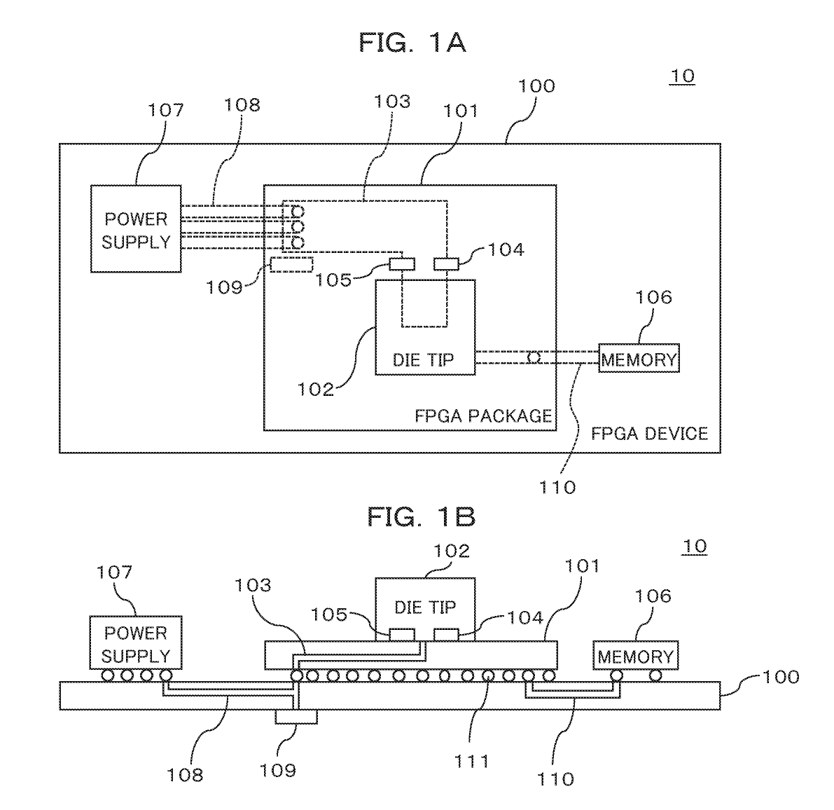

FIG. 1A is a schematic top view of an FPGA device 10, and FIG. 1B is a schematic side view of the FPGA device 10.

The FPGA device 10 includes an FPGA package 101, a memory 106, and a power supply 107 on a board 100. In addition, a bypass capacitor 109 is disposed on the back surface of the board 100.

The board 100 includes a wiring line 108 for connecting the power supply 107, the bypass capacitor 109, and the memory 106 to the FPGA package 101. The board 100 includes a multilayer printed board. As shown in FIG. 1B, the wiring line 108 for connecting the FPGA package 101 with the power supply 107 and a wiring line 110 for connecting the FPGA package 101 with the memory 106 are disposed inside the board 100.

In order for the die chip 102 of the FPGA package 101 to read configuration data, the memory 106 provides a storage area for storing the configuration data.

The power supply 107 is a circuit for supplying a voltage to the FPGA device 10. The voltage to be supplied to the FPGA device 10 by the power supply 107 may be selectable from a plurality of voltages.

The bypass capacitor 109 is a capacitor for accumulating electric charge to reduce fluctuation of a voltage supplied by the power supply 107 in preparation for when the FPGA package 101 temporarily consumes a large amount of current.

The FPGA package 101 includes a die chip 102, a wiring line 103, and capacitors 104 and 105.

The die chip 102 is a semiconductor element inside which a chip of an FPGA is sealed with resin or the like, and is fixed to the FPGA package 101.

The wiring line 103 is a wiring line pattern for being connected to the power supply 107 through the wiring line 108 and for supplying a voltage to the die chip 102.

In the same manner as the bypass capacitor 109, the capacitor 104 and capacitor 105 is a capacitor for accumulating electric charge to reduce fluctuation of a voltage supplied by the power supply 107 in preparation for when the die chip 102 temporarily consumes a large amount of current.

As shown in FIG. 1B, the FPGA package 101 is electrically connected to the board 100 through a plurality of bumps 111, and is fixed to the board 100. Therefore, the FPGA device 10 is an example of a semiconductor device on which a logical device is mounted.

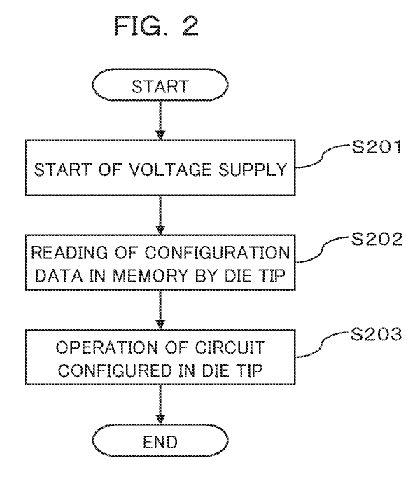

FIG. 2 is a flowchart illustrating an operation of the FPGA device 10. In step S201, the voltage supply to the die chip 102 is started through the wiring line. The start of the voltage supply supplies the output voltage of the power supply 107 to the die chip 102 through the wiring line 108 and the wiring line 103. By the voltage supply, the die chip 102 starts the operation, and reads the configuration data stored in the memory 106 in step S202. Depending on the read configuration data, the setting of the switches and the like included in the FPGA inside the die chip 102 is performed, and the circuit corresponding to the configuration data is configured in the FPGA inside the die chip 102. When the circuit is configured, the operation of the circuit configured in the FPGA inside the die chip 102 starts in step S203.

The circuit configured in the die chip 102 can include not only logic circuits but also sequential circuits, and can achieve a function equivalent to that of causing a CPU (Central Processing Unit) to execute a program. Therefore, unlike the conventional LSI (Large Scale Integrated circuit) or the like, the die chip 102 has a consumption current with variable frequency fluctuation, and the consumption current changes depending on the load condition and the like as time elapses. For this reason, in the FPGA device 10, the voltage to be supplied from the power supply 107 may fluctuate greatly.

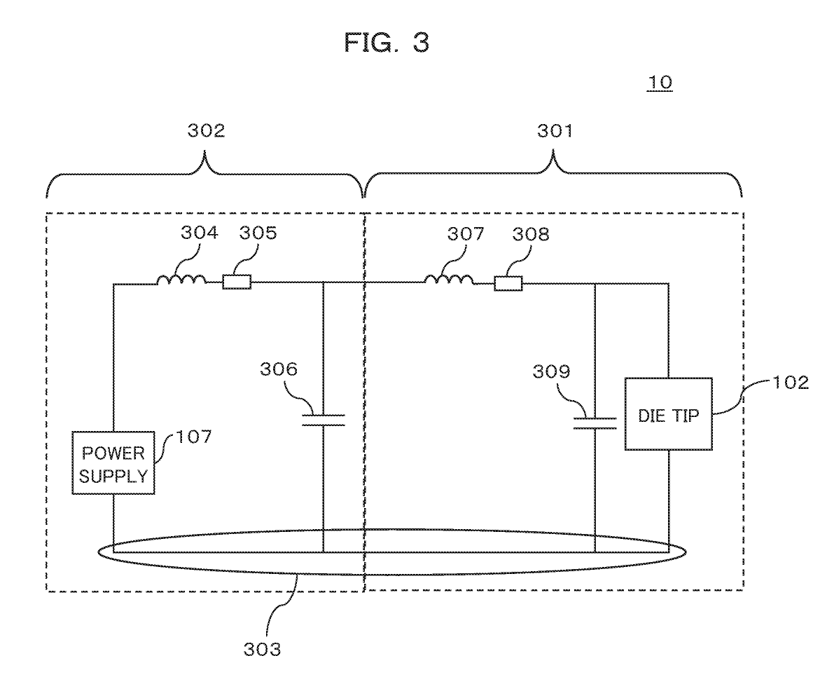

FIG. 3 is an equivalent circuit diagram of the FPGA device 10. The region of reference numeral 301 is an equivalent circuit of the FPGA package 101, and the region of reference numeral 302 is an equivalent circuit of the power supply 107 and the wiring line 108. The power supply 107 and the die chip 102 are connected to the ground wiring line 303 as indicated by reference numeral 303 by the wiring line 108 and the wiring line 103, and share the ground level. In this case, due to the ground wiring line 303, the wiring line for supplying the voltage, and the capacitors 104 and 105 for stabilizing the voltage, the capacitance 309 exists in parallel with the die chip 102. In addition, the inductance 307 and the resistance 308 exist in the wiring line 103.

In addition, also in the equivalent circuit of reference numeral 302, due to the ground wiring line 303, the wiring line 108 for supplying a power supply, and the bypass capacitor 109, the capacitance 306 exists in parallel with the power supply 107. In addition, the inductance 304 and the resistance 305 exist in the wiring line 108.

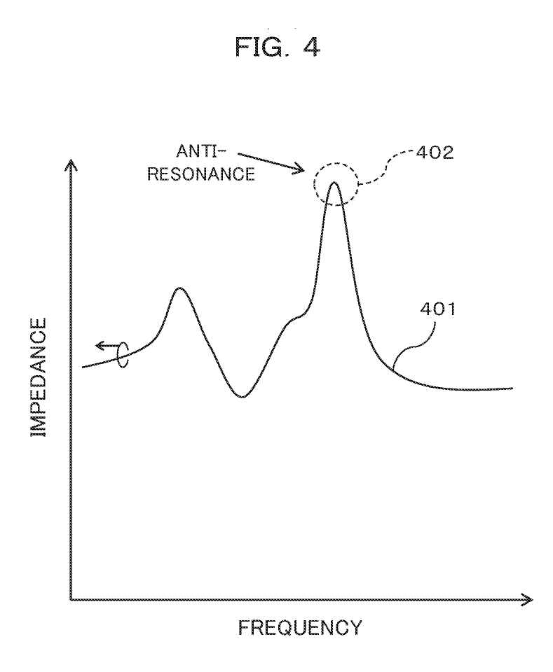

Therefore, the impedance determined by the characteristic of the equivalent circuit shown in FIG. 3 is not constant with respect to the frequency fluctuation of the consumption current of the circuit configured in the FPGA, and fluctuates, for example, as shown by the graph 401 in FIG. 4. In addition, the anti-resonance point 402 where the impedance sharply increases may exist in the frequency fluctuation range of the consumption current of the circuit configured in the FPGA. The reason why the anti-resonance point 402 exists is that the capacitance 306 and 309 are connected in parallel, and the capacitance 306 and 309 are connected through the inductance 304 and 307 and the resistance 305 and 308. It should be noted that the frequency of the anti-resonance point 402 is referred to as an anti-resonance frequency.

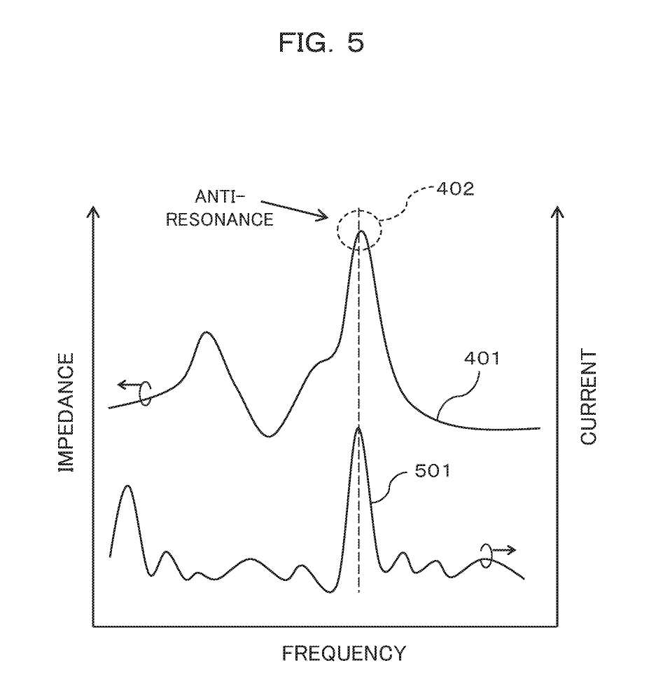

From the viewpoint of the die chip 102, when the peak frequency of the consumption current of the circuit configured in the FPGA approaches the anti-resonance frequency, the impedance of the power supply circuit including the power supply 107 sharply increases at the peak frequency. This leads to a sharp increase in the consumption current of the die chip 102 as shown by the graph 501 in FIG. 5. Although as the consumption current increases, the current is temporarily supplied due to the capacitors 104 and 105 and the bypass capacitor 109, when the supply is terminated, the voltage of the power supply 107 drops.

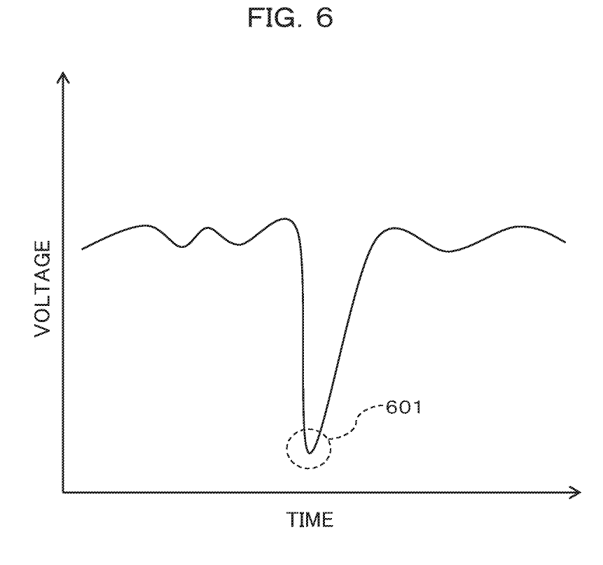

FIG. 6 is a diagram illustrating an example of a voltage characteristic with respect to an operating time of the FPGA device. The reference numeral 601 in FIG. 6 indicates that the peak frequency of the consumption current of the circuit configured in the FPGA matches the anti-resonance frequency, and that the voltage of the power supply 107 drops sharply. When the voltage of the power supply 107 drops sharply, a malfunction of the circuit in the die chip 102 occurs, and the operation of the circuit may be different from the designed operation due to the malfunction. Subsequently, when the frequency fluctuation of the consumption current of the circuit configured in the FPGA moves away from the anti-resonance frequency, the voltage of the power supply 107 recovers, and the circuit configured in the FPGA performs the operation as designed. However, when the circuit in the die chip 102 includes a sequential circuit, the influence of the malfunction remains, and there are cases where the influence of the malfunction may be revealed later. For this reason, it may be difficult to distinguish whether the malfunction is caused by the erroneous design of the sequential circuit or the voltage drop of the power supply 107.

Therefore, it is desired to design the board 100 and the FPGA package 101 so as to shift the anti-resonance frequency from the peak frequency of the consumption current of the circuit configured in the FPGA. However, even after manufacturing, the FPGA device 10 can change the circuit configured in the FPGA at the time of operation by changing the configuration data. Therefore, the circuit in the FPGA is not able to be determined at the time of designing the board 100 including the power supply 107 and the FPGA package 101, and it is difficult to determine the frequency fluctuation of the consumption current of the circuit configured in the FPGA. Therefore, it is difficult to design the board 100 and the FPGA package 101 in advance so as to shift the anti-resonance frequency from the peak frequency of the consumption current of the circuit configured in the FPGA. In addition, it is not realistic either to generate configuration data in order not to include the anti-resonance frequency in the frequency fluctuation range of the consumption current of the circuit configured in the FPGA.

In order to suppress the occurrence of the voltage drop as described above, the following embodiments will be described.

### First Embodiment

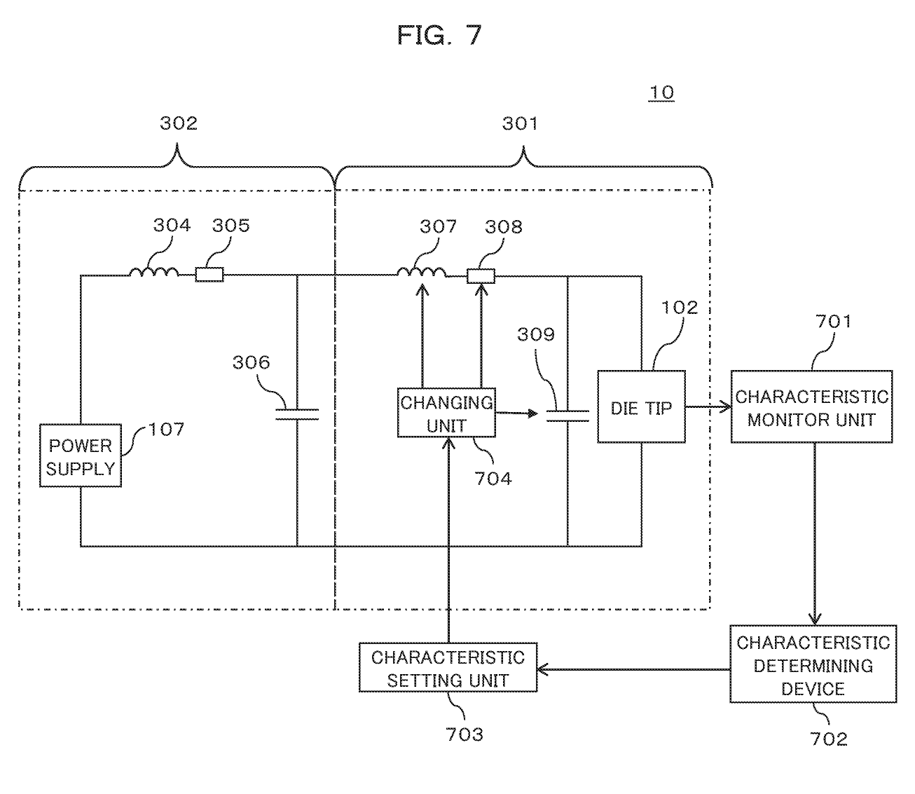

FIG. 7 is an equivalent circuit diagram of the FPGA device 10 according to a first embodiment. In the equivalent circuit of the FPGA device 10, one or more of the capacitance 309, the resistance 308, and the inductance 307 can be changed by the changing unit 704.

For example, the inductance 307 can be obtained by a plurality of coils, a wiring line having a meander structure, and the like. Operation of the switch of the changing unit 704 changes the connection relation between the plurality of coils and the wiring line having a meander structure during the operation of the circuit configured in the die chip 102. Making the connection relation between the plurality of coils in series increases the inductance 307, and making this in parallel decreases the inductance 307. Similarly, the connection relation between the plurality of resistors and capacitors may be changed by the changing unit 704.

The changing unit 704 changes the connection relation between one or more of the coil, the resistor and the capacitor. The changing unit 704 reads, for example, a value representing the connection relation from the nonvolatile memory and controls the switch depending on the contents stored in the memory.

In addition, the capacitance 309 is obtained by a variable capacitance capacitor whose capacitance is variable by application of a voltage, and the changing unit 704 may change the voltage applied to the variable capacitance capacitor. In this case, the information about the voltage to be applied to the variable capacitance capacitor is stored in the memory of the changing unit 704.

The setting of change of the inductance 307 and the like by the changing unit 704 is performed by the characteristic setting unit 703. The characteristic setting unit 703 writes information into the storage area of the memory included in the changing unit 704 so that at least one of the capacitance 309, the resistance 308, and the inductance 307 has a desired value.

For the setting by the characteristic setting unit 703, the characteristic monitor unit 701 monitors the characteristic of fluctuation of the consumption current of the circuit configured in the FPGA. The characteristic monitor unit 701 is a measuring device capable of measuring fluctuation in current and voltage with respect to frequency, such as a spectrum analyzer and an oscilloscope.

The monitoring result by the characteristic monitor unit 701 is input into a characteristic determining device 702 to determine the characteristic of the wiring line 103.

It should be noted that the characteristic setting unit 703 and the characteristic monitor unit 701 are not necessarily connected to the FPGA device 10 all the time. It is only necessary that the setting unit 703 be connected to the FPGA device 10 when the setting of the change of the inductance 307 and the like by the changing unit 704 is performed. In addition, it is only necessary for the characteristic monitor unit 701 to be connected to the FPGA device 10 when the characteristic of fluctuation in the consumption current of the circuit configured in the FPGA is monitored.

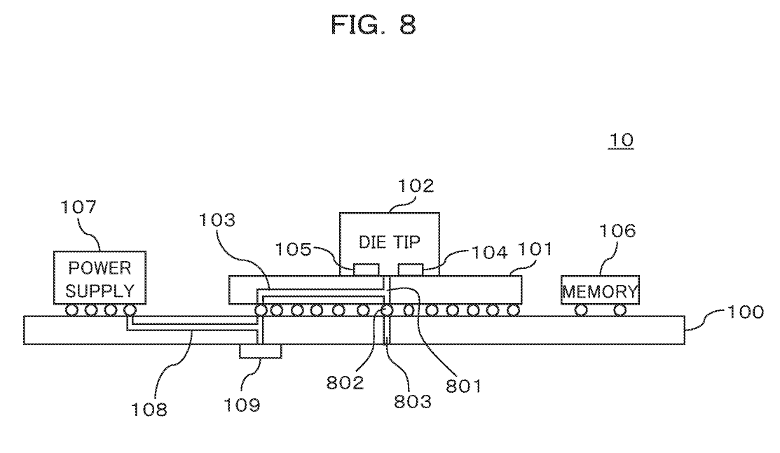

FIG. 8 is a schematic side view of the FPGA device 10 according to the present embodiment. When FIG. 1B and FIG. 8 are compared with each other, in the FPGA device 10 shown in FIG. 8, a through via 803 and a through via 801 are provided in the board 100 and the FPGA package 101, respectively. The through via 801 is connected to the wiring line 103 in the FPGA package 101. In addition, the through via 801 and the through via 803 are electrically connected to each other through the bump 802.

Therefore, the lower end of the through via 803 functions as a terminal. A device that measures the relation between frequency and voltage or current such as a spectrum analyzer can be connected to the through via 803 as a measuring device. The characteristic related to frequency fluctuation of the consumption current due to the circuit configured in the FPGA can be measured by operation of the FPGA device 10 under various conditions.

The through via 803, the through via 801, and the bump 802 can be disposed in any position as long as the through via 803 is electrically connected to the wiring line 103. However, in order to more accurately measure the characteristic related to frequency fluctuation of the consumption current due to the circuit configured in the FPGA, the smaller the distance between the die chip 102 and the through via 803, the better. For this reason, the through via 803, the through via 801, and the bump 802 may be disposed directly under the die chip 102.

The characteristic monitor unit 701 monitors the operating characteristic of the FPGA. As a result of the monitor, when the peak frequency of the consumption current due to the circuit configured in the FPGA matches or approaches the anti-resonance frequency, the characteristic setting unit 703 changes the data stored in the changing unit 704. Changing the data to be stored causes the changing unit 704 to change the value of any one or more of the capacitance 309, the resistance 308, and the inductance 307 from the current value and to change the anti-resonance frequency to shift from the peak frequency of the consumption current. The data to be stored in the changing unit 704 in order that the anti-resonance frequency is shifted from the peak frequency of the consumption current (to be made substantially different) can be determined at the time of designing of the board 100 and the FPGA package 101 and the like. This is because the anti-resonance frequency is determined independently of the configuration data of the FPGA.

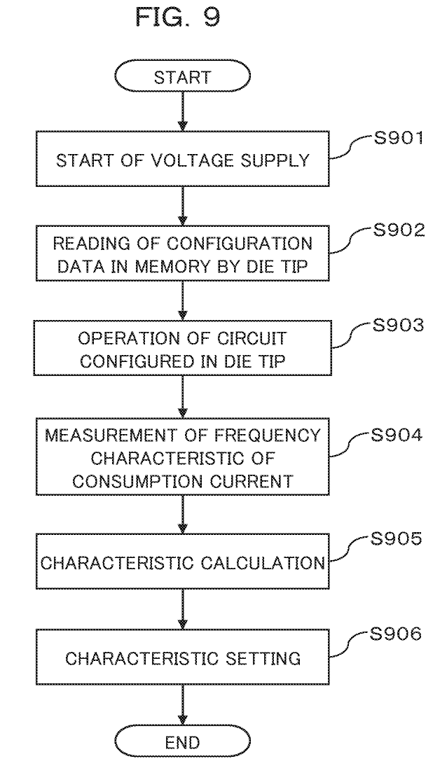

FIG. 9 is a flowchart illustrating an example of processing for changing an anti-resonance frequency of the FPGA device 10 according to the present embodiment. In step S901, the voltage supply is started. The start of the voltage supply supplies a voltage to the die chip 102 through the wiring line 108 and the wiring line 103. The start of the voltage supply causes the die chip 102 to read the configuration data stored in the memory 106 in step S902. Depending on the read configuration data, the setting of the switches and the like included in the FPGA inside the die chip 102 is performed, and the circuit corresponding to the configuration data is configured in the FPGA inside the die chip 102. When the circuit is configured, the operation of the circuit configured in the FPGA inside the die chip 102 starts in step S903.

In step S904, the characteristic monitor unit 701 measures the frequency characteristic of the consumption current due to the circuit configured in the FPGA. In step S905, the characteristic setting unit 703 calculates the characteristic to be set. For example, the characteristic determining device 702 performs the identification of the anti-resonance frequency and the identification of the frequency range where the voltage drops. The characteristic determining device 702 or the like calculates the values of the capacitance 309, the resistance 308, and the inductance 307 for shifting the identified anti-resonance frequency and the frequency range where the voltage drops to the outside of the range of frequency fluctuation. In step S906, the characteristic setting unit 703 performs the setting of the characteristic calculated in step S905.

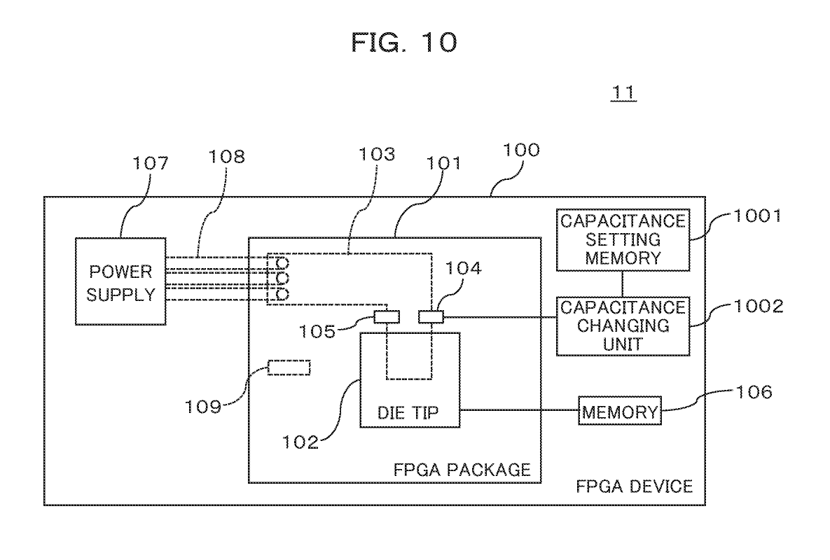

FIG. 10 is a schematic top view of the FPGA device 10 according to the present embodiment. Compared with the top view of the FPGA device 10 shown in FIG. 1A, the top view in FIG. 10 shows a capacitance setting memory 1001 and a capacitance changing unit 1002 as the changing unit 704. In this example, the capacitance changing unit 1002 shifts the anti-resonance frequency from the peak frequency of the consumption current due to the circuit configured in the FPGA by changing the capacitance of the capacitor 104 mounted on the FPGA package 101.

The capacitance setting memory 1001 includes a nonvolatile memory configured to store a value after the change in the capacitance of the capacitor 104 by the capacitance changing unit 1002. The capacitance setting memory 1001 may be implemented by the memory 106. The start of the voltage supply causes the capacitance changing unit 1002 to read the value stored in the capacitance setting memory 1001 and to change the capacitance of the capacitor 104 based on the read value. For example, when the capacitor 104 is formed by a plurality of capacitors to which switches are connected, setting of a switch connected to a capacitor is performed, the connection relation of the capacitors is changed, and the capacitance is changed. Alternatively, if the capacitor 104 is a variable capacitance capacitor whose capacitance is changed depending on the application of a voltage, the capacitance changing unit 1002 applies a voltage corresponding to a value stored in the capacitance setting memory 1001 to the variable capacitance capacitor.

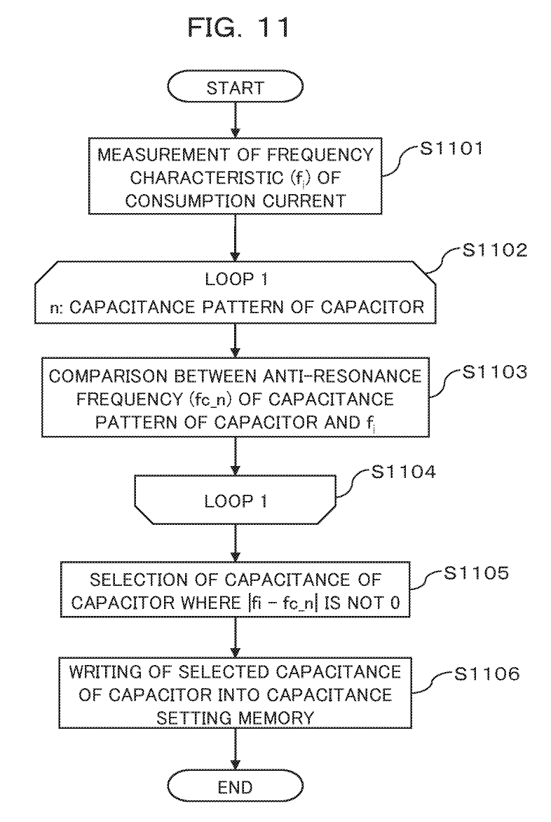

FIG. 11 is a flowchart illustrating another example of processing for changing the anti-resonance frequency of the FPGA device 10, and is a flowchart for explaining in detail the processing of steps S904 to S906 in the flowchart illustrated in FIG. 9.

Step S1101 corresponds to step S904, and the frequency characteristic (fi) of the consumption current is measured by the characteristic monitor unit 701. Steps S1102 to S1104 form a loop, and each time the pattern of the capacitance of the capacitor (the capacitance value of the capacitor after the change by the capacitance changing unit 1002) is selected, the steps go around the loop once to execute step S1103. In step S1103, the anti-resonance frequency (fc_n) in the case of changing to the capacitance pattern of the selected capacitor is calculated.

In step S1105, the capacitance of the capacitor where the anti-resonance frequency is not included within the frequency range of the frequency characteristic fi is selected. Here, |fi−f| for the frequency characteristic fi and the frequency f is defined as min |f−g| for any frequency g in the frequency range of the frequency characteristic fi. Therefore, if f is included within the frequency range of the frequency characteristic fi, |fi−f|=0 is obtained. On the other hand, |fi−f| does not become 0 if f is not included in the frequency range of the frequency characteristic fi, and takes a larger value as f deviates from the frequency range of the frequency characteristic fi. Step S1105 corresponds to step S905.

In step S1105, the capacitance of the capacitor where |fi−fc_n| does not become 0 for the frequency characteristic fi is selected. In this case, it is preferable to select the capacitance of the capacitor where |fi−fc_n| is the largest. This is because the possibility that the frequency fluctuation of the current when the FPGA is actually operated coincides with the anti-resonance frequency becomes smaller as the anti-resonance frequency deviates from the frequency range of the frequency characteristic fi.

In step S1106, the capacitance of the capacitor selected in step S1105 is written into the capacitance setting memory 1001. Step S1106 corresponds to step S906.

As described above, in the present embodiment, the characteristic monitor unit 701 is connected to the die chip 102, and the frequency characteristic of the die chip 102 is measured. Setting is performed so that a value of at least one of the capacitance 309, the resistance 308, and the inductance 307 is changed by the changing unit 704 based on the measurement result. Therefore, even if the configuration data are changed, the anti-resonance frequency can be shifted from the peak frequency of the consumption current due to the circuit configured in the FPGA. This allows the FPGA to be operated stably. In addition, the voltage drop due to the anti-resonance frequency is suppressed, and therefore miniaturization of the power supply 107 can be achieved. Furthermore, identification of the cause when the malfunction of the FPGA occurs becomes easy.

### Second Embodiment

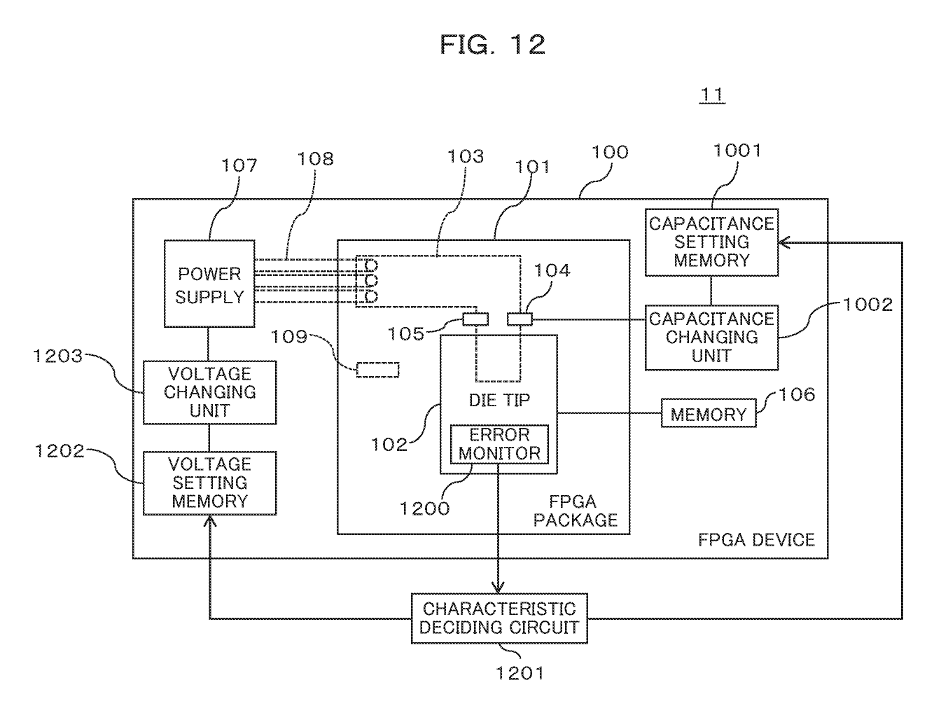

FIG. 12 is a functional block diagram of an FPGA device 11 according to a second embodiment. The FPGA device 11 is the FPGA device 10 shown in FIG. 10 further including a voltage setting memory 1202 and a voltage changing unit 1203. In addition, in order to decide the operating characteristic of the FPGA device 11, a characteristic deciding circuit 1201 is used as the characteristic monitor unit 701.

The power supply 107 of the FPGA device 11 has a variable output voltage. The output voltage of the power supply 107 is changed by the voltage changing unit 1203. The voltage changing unit 1203 reads information on the voltage stored in the voltage setting memory 1202 at the start of the operation of the FPGA device 11, and changes the output voltage of the power supply 107 based on the read information. This allows the voltage to be supplied to the die chip 102 to be changed. It should be noted that the voltage setting memory 1202 may be implemented by the memory 106.

The characteristic deciding circuit 1201 monitors the operation of the circuit configured in the FPGA. In order for the characteristic deciding circuit 1201 to monitor the operation of the circuit configured in the FPGA, the circuit configured in the FPGA includes an operation monitor circuit. As an example of the operation monitor circuit, there is an error monitor 1200 for detecting an operation error. The characteristic deciding circuit 1201 monitors the output of the error monitor 1200 being an example of the operation monitor circuit.

The error monitor 1200 is a circuit for monitoring an operation error due to another circuit portion configured in the die chip 102. Specifically, the error monitor 1200 monitors whether the operation result by the circuit configured in the die chip 102 is correct. For example, the error monitor 1200 monitors the parity of the output of the circuit configured in the die chip 102 and monitors whether or not an error occurs in the parity.

The characteristic deciding circuit 1201 can also set the capacitance setting memory 1001, and the change in setting of the capacitance setting memory 1001 allows the change in the capacitance of the capacitor 104 through the capacitance changing unit 1002.

With the set capacitance of the capacitor 104, the characteristic deciding circuit 1201 can select one output voltage from a plurality of output voltages of the power supply 107, and can operate the FPGA device 11. If no error is detected by the error monitor 1200, it can be confirmed that the capacitance of the capacitor 104 at that time and the output voltage of the power supply 107 correctly operate the FPGA device 11.

Thus, various combinations of the capacitance of the capacitor 104 and the output voltage of the power supply 107 make it possible to confirm whether the FPGA device 11 can operate properly or malfunction occurs. Then, for example, the capacitance of the capacitor 104 in which no malfunction occurs even if the output voltage of the power supply 107 is made the lowest can be determined. As a result, low power consumption of the FPGA device 11 can be achieved while malfunction of the FPGA is avoided.

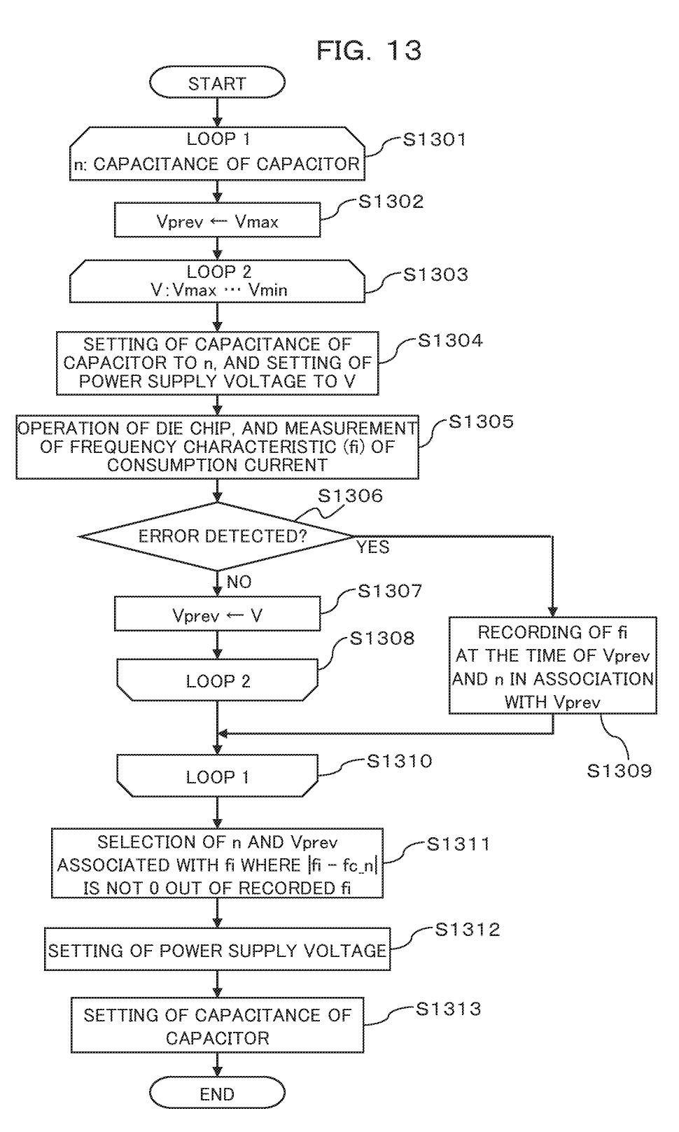

FIG. 13 is a flowchart illustrating an example of processing for changing an anti-resonance frequency of the FPGA device according to the second embodiment. Steps S1301 to S1310 form a loop 1 being a first loop. The loop 1 is executed once for each value of the capacitance of the capacitor 104. In the following, the capacitance of the capacitor 104 is substituted into the variable n.

In step S1302, Vmax is substituted into the variable Vprev. The Vmax represents the maximum value of the voltage that the power supply 107 can output. The Vprev is a variable representing the maximum value of the voltage at which the FPGA device 11 operates correctly.

Steps S1303 to S1308 form a loop 2 being a second loop. The loop 2 is executed once for each voltage that the power supply 107 can output. In the following, a voltage that the power supply 107 can output is substituted into the variable V in order of a higher voltage to a lower voltage.

In step S1304, the output voltage of the power supply 107 is set to the value of the variable V. In step S1305, the circuit configured in the die chip 102 is operated, and the frequency characteristic related to the frequency fluctuation of the consumption current due to the circuit configured in the FPGA is measured. The measured frequency characteristic is represented by fi.

In step S1306, it is determined whether an error is detected by the error monitor 1200. If no error is detected, the process branches into No, and the process to be executed next is step S1307. If an error is detected, the process branches into Yes, and the process to be executed next is step S1309.

In step S1307 (if no error is detected in step S1306), the value of the variable V is substituted into the variable Vprev. As a result, the value of the output voltage of the power supply 107 when no error is detected is substituted into the variable Vprev. Upon completion of step S1307, the process returns to step S1303, and the loop 2 is executed for the next value of the V. If the loop 2 is executed for all V values, the next process to be executed is step S1310, and the loop 1 is executed for the capacitance value of the next capacitor. If the loop 1 is executed for the capacitance values of all of the capacitors, the next process to be executed is step S1311.

In step S1309 (when an error is detected in step S1306), the value substituted into the variable Vprev represents the lower limit of the value of the output voltage of the power supply 107 that is operated without error. In step S1309, fi and n are recorded in association with the Vprev. Upon completion of the process of step S1309, the process exits the loop 2, returns to step S1301, substitutes the capacitance of the next capacitor 104 for the variable n, and executes the loop 1. If there is no capacitance of the next capacitor 104, the loop 1 is terminated, and the next process is step S1311.

In step S1311 after exiting the loop 1, the process selects n and Vprev associated with fi where |fi−fc_n| is not equal to 0 out of the recorded fi.

In step S1312, the output voltage of the power supply 107 is set to the selected variable Vprev.

In step S1313, the capacitance of the capacitor is set to the value substituted into the variable n.

It should be noted that steps S1312 and S1313 may be executed in the reverse order.

In addition, in the above description, in step S1312, the power supply voltage is set to the selected Vprev; this is because the lower limit of the voltage at which the circuit configured in the die chip 102 moves correctly is substituted into the Vprev, and the die chip 102 is to be operated at a lower voltage. If the die chip 102 is not to be operated at a low voltage, the voltage may be set to a value larger than the Vprev (for example, Vmax). By this setting, an operation margin of a large voltage can be secured.

As described above, in the present embodiment, an error monitor can be included in the circuit configured in the die chip 102, and the presence or absence of a malfunction can be monitored. Therefore, in addition to the effects of the first embodiment, the output voltage of the power supply 107 and the capacitance of the capacitor 104 within a range in which no malfunction actually occurs can be selected, and the FPGA can be stably operated.

### Third Embodiment

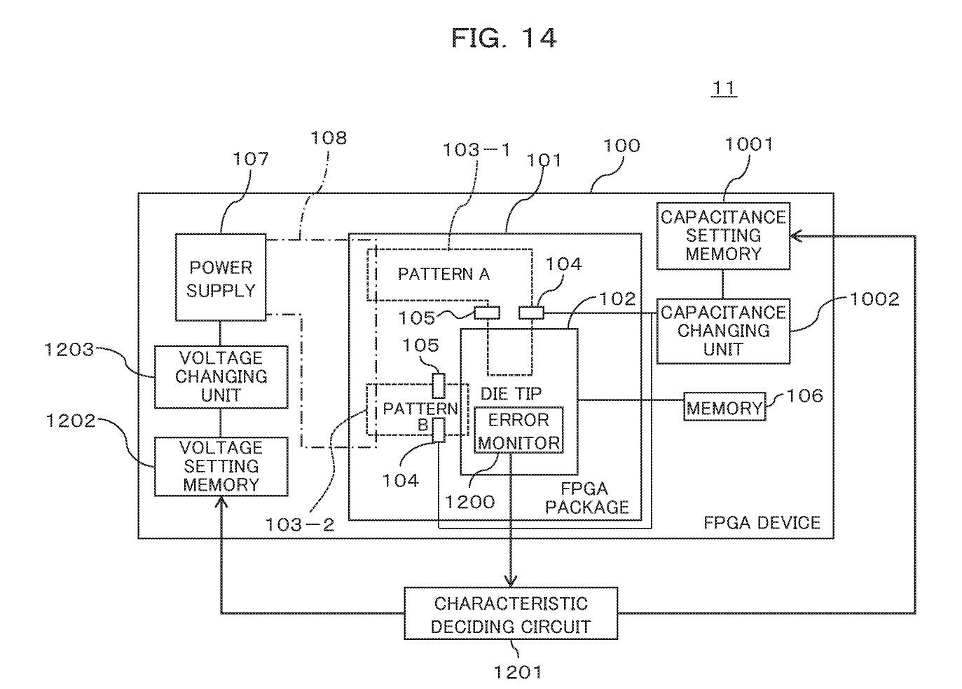

FIG. 14 is a schematic top view of the FPGA device 11 according to a third embodiment. In the present embodiment, in addition to selection of the output voltage of the power supply 107 and the capacitance of the capacitor 104 in the second embodiment, a plurality of wiring lines to be connected to the power supply 107 can be selected. The plurality of wiring lines of the power supply can have characteristics different from each other. Therefore, the characteristic of the wiring line of the power supply can be diversified by addition of the selection of the wiring line.

As shown in FIG. 14, in the FPGA package 101, a pattern A (103-1) and a pattern B (103-2) are formed as the wiring line. The pattern A (103-1) and the pattern B (103-2) have different pattern shapes, and the inductance, the resistance, and the capacitance with the ground wiring line are different. In addition, which of the pattern A (103-1) and the pattern B (103-2) is selected can be selected depending on the configuration data stored in the memory 106. Therefore, the wiring line can be selected depending on the setting of the configuration data.

The method of selecting which of the pattern A (103-1) and the pattern B (103-2) is, first, selecting the pattern A (103-1), executing the process of the flowchart in FIG. 13, and obtaining the minimum output voltage of the power supply 107; next, selecting the pattern B (103-2), executing the flowchart in FIG. 13, and obtaining the minimum output voltage of the power supply 107; and then, selecting the lower pattern of the minimum output voltage of the power supply 107.

According to the present embodiment, in addition to the effects of the second embodiment, the anti-resonance frequency can be shifted from the peak frequency of the consumption current by the selection of the power supply wiring line pattern. This allows the FPGA to be operated stably.

(Usage Example for Communication Apparatus)

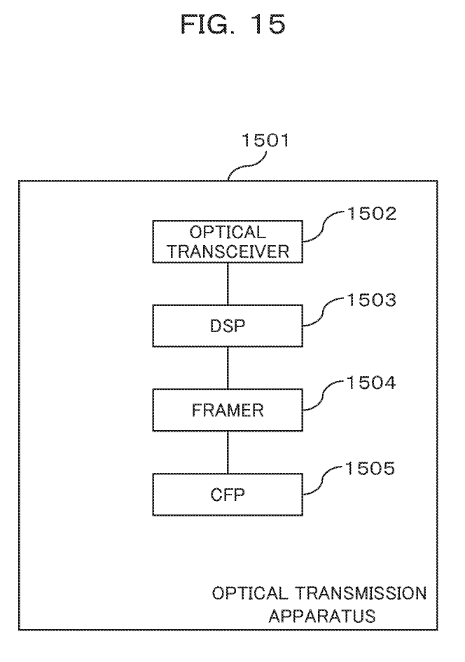

FIG. 15 is a functional block diagram of an optical transmission apparatus 1501 using an FPGA device according to any one of the above embodiments. In FIG. 15, the optical transmission apparatus 1501 includes an optical transceiver 1502, a DSP 1503, a framer 1504, and a CFP 1505. The optical transmission apparatus 1501 is an example of the communication apparatus. DSP stands for Digital Signal Processor. CFP stands for Centum Gigabit Form Factor Pluggable.

The CFP 1505 is an example of a transceiver. An external apparatus is connected to the CFP 1505, and a signal transmitted and received by the optical transmission apparatus 1501 is input and output from and to the external apparatus as an electric signal through the CFP 1505.

The framer 1504 performs conversion between the format of the electric signal input and output through the CFP 1505 and the frame format of the digital signal.

The DSP 1503 multiplexes the digital signal input from the framer 1504 to convert into an analog signal, and outputs the converted analog signal to the optical transceiver 1502. In addition, the DSP 1503 converts the analog signal received from the optical transceiver 1502 into a digital signal, performs the digital signal processing on the converted digital signal, and eliminates the influence of waveform distortion and the like when the optical signal is transmitted through the optical transmission line.

The optical transceiver 1502 functions as an I/O interface unit of the optical signal. The optical transceiver 1502 modulates the multiplexed signal output from the DSP 1503 into an optical signal, and transmits the optical signal to the opposite optical transmission apparatus. In addition, the optical transceiver 1502 converts the optical signal received from the opposite optical transmission apparatus into an electrical signal, and outputs the converted electrical signal to the DSP 1503.

The FPGA device 10 or 11 described above can be used for the DSP 1503. The bit rate of optical transmission by the optical transmission apparatus 1501 may exceed 100 gigabits per second, and the DSP 1503 is required to perform high-speed processing. In addition, today, the optical transmission technology is a part of social infrastructure, and high reliability is required for the optical transmission apparatus.

Therefore, the DSP 1503 is implemented by using the above FPGA device 10 or 11, whereby the complex processing can be achieved by the hardware configuration, high-speed processing can be achieved and can be stably operated in a wide operating frequency range.

In addition, the FPGA devices 10 and 11 are not intended to be limited to being used for achieving the function of the DSP 1503, and can also be used for the processing of the framer 1504. In addition, the FPGA devices 10 and 11 can also be used for conversion between analog signals and digital signals. The FPGA devices 10 and 11 can be used, for example, for achieving the function of the CFP 1505.

In addition, the FPGA devices 10 and 11 are not limited to the use for the optical transmission apparatus 1501, and can be used in an apparatus for performing any one or both of the digital signal processing and the conversion between analog signals and digital signals. For example, the FPGA devices 10 and 11 can be used for achieving all or part of the functions of a mobile phone, a base station of a mobile phone, an audio device, and the like.

In addition, even if there should be a malfunction with the FPGA device, it is possible to deal with the malfunction by rewriting the configuration data. In addition, similar measures can be taken even when new processing is added.

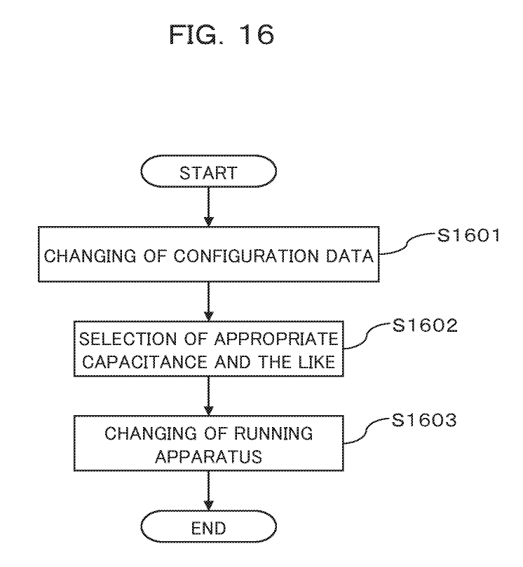

FIG. 16 is a flowchart illustrating an example of configuration data change processing of the FPGA device according to an embodiment.

The configuration data are changed in step S1601 due to the change in the circuit configuration accompanied by repair of the malfunction and addition of new processing.

In step S1602, appropriate capacitance of a capacitor and the like are selected by the application of the configuration data to the FPGA device 10 or 11 and the performance of the processing of the flowchart in FIG. 13 and the like.

In step S1603, the configuration data of the operating optical transmission apparatus and the storage contents of the capacitance setting memory are changed.

As described above, by change in data, repair of malfunctions and addition of new processing can be dealt with, and rapid modification and addition of processing can be dealt with without exchange of hardware elements.

According to the present embodiment, occurrence of voltage drop can be suppressed even if a circuit configured in a programmable logical device is changed.

All examples and conditional language provided herein are intended for the pedagogical purposes of aiding the reader in understanding the invention and the concepts contributed by the inventor to further the art, and are not to be construed limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A communication apparatus comprising:
a programmable logical device;
at least one wiring line configured to supply a voltage to the logical device; and
a changing unit configured to change a frequency characteristic of the at least one wiring line based on an operating characteristic obtained by monitoring of the operating characteristic of the logical device configured to operate by receiving supply of the voltage.

2. The communication apparatus according to claim 1,
further comprising a storage area configured to store a first value representing the operating characteristic, and
wherein the changing unit changes the frequency characteristic of the at least one wiring line based on the first value stored in the storage area.

3. The communication apparatus according to claim 1, wherein the changing unit changing the frequency characteristic of the at least one wiring line includes shifting an anti-resonance frequency possessed by the at least one wiring line from a peak frequency in a frequency characteristic of a current consumed by the logical device.

4. The communication apparatus according to claim 1, wherein the changing unit changes any one or more of inductance, resistance, and capacitance possessed by the at least one wiring line.

5. The communication apparatus according to claim 1,
wherein the at least one wiring line configured to supply a voltage to the logical device is selectable from a plurality of wiring lines, and
wherein the logical device selects the at least one wiring line to be used from the plurality of wiring lines.

6. The communication apparatus according to claim 2,
wherein the voltage to be supplied to the logical device is selectable,
wherein the storage area stores a second value representing the voltage selected out of selectable voltages, and
wherein the changing unit changes the voltage to be supplied to the logical device based on the second value stored in the storage area.

7. The communication apparatus according to claim 1, further comprising a terminal for monitoring a frequency characteristic of a current to be supplied to the logical device.

8. A semiconductor device comprising:
a programmable logical device;
at least one wiring line configured to supply a voltage to the logical device; and
a changing unit configured to change a frequency characteristic of the at least one wiring line based on an operating characteristic obtained by monitoring of an operating characteristic of the logical device configured to operate by receiving supply of the voltage.

9. The semiconductor device according to claim 8,
further comprising a storage area configured to store a first value representing the operating characteristic, and
wherein the changing unit changes the frequency characteristic of the at least one wiring line based on the first value stored in the storage area.

10. The semiconductor device according to claim 8, wherein the changing unit changing the frequency characteristic of the at least one wiring line includes shifting an anti-resonance frequency possessed by the at least one wiring line from a peak frequency in a frequency characteristic of a current consumed by the logical device.

11. The semiconductor device according to claim 8, wherein the changing unit changes any one or more of inductance, resistance, and capacitance possessed by the wiring line.

12. The semiconductor device according to claim 8,
wherein the at least one wiring line configured to supply a voltage to the logical device is selectable from a plurality of wiring lines, and
wherein the logical device selects the at least one wiring line to be used from the plurality of wiring lines.

13. The semiconductor device according to claim 9,
wherein the voltage to be supplied to the logical device is selectable,
wherein the storage area stores a second value representing the voltage selected out of selectable voltages, and
wherein the changing unit changes the voltage to be supplied to the logical device based on the second value stored in the storage area.

14. The semiconductor device according to claim 8, further comprising a terminal for monitoring a frequency characteristic of a current to be supplied to the logical device.

15. A frequency characteristic changing method comprising changing a frequency characteristic possessed by at least one wiring line configured to supply a voltage to a programmable logical device, based on an operating characteristic obtained by monitoring of the operating characteristic of the logical device configured to operate by receiving supply of the voltage.

16. The frequency characteristic changing method according to claim 15, wherein the step of changing the frequency characteristic of the at least one wiring line includes shifting an anti-resonance frequency possessed by the at least one wiring line from a peak frequency in a frequency characteristic of a current to be consumed by the logical device.

17. The frequency characteristic changing method according to claim 15, wherein the step of changing the frequency characteristic of the at least one wiring line includes changing any one or more of inductance, resistance, and capacitance possessed by the at least one wiring line.

18. The frequency characteristic changing method according to claim 17, wherein the step of changing any one or more of inductance, resistance, and capacitance possessed by the at least one wiring line includes selecting one wiring line from a plurality of wiring lines, and supplying the voltage to the logical device by the selected wiring line.

19. The frequency characteristic changing method according to claim 15,
further comprising monitoring the operating characteristic of the logical device,
further comprising storing a value representing the operating characteristic in a storage area based on the monitored operating characteristic, and
further comprising reading the value representing the operating characteristic from the storage area, and changing the frequency characteristic possessed by the at least one wiring line configured to supply the voltage to the logical device.

20. The frequency characteristic changing method according to claim 15,
further comprising configuring a detection circuit configured to detect an operation error of the logical device in the logical device, and
wherein the step of monitoring the operating characteristic of the logical device includes monitoring whether the operation error is detected by the detection circuit.

21. The frequency characteristic changing method according to claim 20, wherein the step of monitoring the operating characteristic of the logical device is performed by changing of the voltage supplied to the logical device.

22. The frequency characteristic changing method according to claim 21, further comprising selecting a lower limit of a voltage range, where the operation error is not detected by the detection circuit, out of selectable voltages to supply the lower limit as the voltage to the logical device.
